(19) United States
(12) Patent Application Publication
(10) Pub. No.: US 2009/0059540 A1
(43) Pub. Date: Mar. 5, 2009

(54) SHIELDED HIGH-FREQUENCY CIRCUIT MODULE

(76) Inventors: Kirk S. Giboney, Santa Rosa, CA (US); Paul E. Cassanego, Santa Rosa, CA (US); Xiaohui Qin, Santa Rosa, CA (US); Adam E. Robertson, Provo, UT (US); Brian R. Hutchison, Windsor, CA (US); Robin L. Zinsmaster, Santa Rosa, CA (US)

Correspondence Address: AGILENT TECHNOLOGIES INC., INTELLECTUAL PROPERTY ADMINISTRATION,LEGAL DEPT., MS BLDG. E P.O. BOX 7599, LOVELAND, CO, 80537, US

(21) Appl. No.: 11/848,806

(22) Filed: Aug. 31, 2007

(51) Int. Cl. H05K 9/00; H01R 13/658; H05K 1/14

(52) U.S. Cl. 361/739; 361/816; 439/610

(57) ABSTRACT

A shielded high-frequency circuit module includes a conductive frame electrically coupled to a top surface of a printed circuit board and a lid. The conductive frame includes inner walls, which define a circuit region, at least a portion of which includes a circuit on the top surface of the printed circuit board. The shielded high-frequency circuit module also includes a connector for interfacing the circuit region with high-frequency signals outside the conductive frame, at least a portion of the connector being electrically coupled to the conductive frame. The inner walls of the conductive frame, the top surface of the printed circuit board and the lid define a shield surrounding the circuit region.

### CROSS REFERENCE TO RELATED APPLICATIONS

The present application is related to U.S. patent application Ser. No. 11/608,084 (Agilent Docket No. 10060451-02), filed Dec. 7, 2006, entitled “Shield for a Microwave Circuit Module,” the subject matter of which is incorporated herein by reference.

### BACKGROUND

Electromagnetic shielding improves high frequency (e.g., microwave and millimeter wave) circuit performance by reducing interference among different parts the circuit and from external sources. A circuit is typically electromagnetically shielded by a metal enclosure or shield. Openings are often provided to access signals within the shield, although such openings may degrade the shielding effectiveness.

Typically, components for a millimeter-wave circuit are not designed for use on a printed circuit board (PCB), and millimeter-wave circuit paths using PCB features and processes are not currently practical for most applications. Although PCB technology is attractive for its comparatively low cost and wide availability, manufacturing tolerances of mass-produced PCB fabrication and assembly technology are limiting. Component sizes and tolerances generally decrease as intended operation frequency increases in order to maintain performance. As millimeter-waves have comparatively high frequencies, the effect of a circuit element of a given size becomes more pronounced. Unintended circuit elements are undesirable and are called “parasitic elements.” For example, parasitic inductors may result in millimeter wave circuits and can impact the performance of the circuit. Parasitic elements may arise from misalignment of circuit features, for example, which can occur due to misalignment of layers in the PCB or from misalignment of components assembled to the PCB.

Millimeter wave circuits may be incorporated into a hybrid microcircuit, having a metal body closed with a metal lid. However, hybrid microcircuits typically support very little integration with respect to incorporation of shielded microwave circuits. For example, bias and support circuitry in hybrid microcircuits is usually only practical and/or cost-effective with the use of a separate PCB. Therefore, hybrid microcircuits generally require separate, interconnected assemblies for low-frequency and high-frequency functions, and have more parts and assembly levels than a single integrated assembly. Also, low-frequency connections to a hybrid microcircuit are typically made through DC feeds, which are pins (wires) supported by dielectric within a coaxial metal sleeve.

Accordingly, known hybrid microcircuits are often comparatively larger and bulkier, and typically have relatively high manufacturing costs, as compared to PCBs. Moreover, many of the parts and assembly processes are not amenable to high-speed automation, especially since fabrication of the metal body is serial rather than batch. Also, the low integration limits functional density, which may compromise performance due to excess losses and lower frequency circuit resonances.

There is a need, therefore, for high-frequency circuits and shielding thereof, that overcomes at least the drawbacks discussed above.

### SUMMARY

In a representative embodiment, a shielded high-frequency circuit module includes a conductive frame electrically coupled to a top surface of a printed circuit board and a lid. The conductive frame includes inner walls defining a circuit region, at least a portion of the circuit region including a circuit on the top surface of the printed circuit board. The shielded high-frequency circuit module further includes a connector adapted to interface the circuit region with high-frequency signals outside the conductive frame, with the connector comprising an outer conductor disposed within the conductive frame and at least a portion of the connector being electrically coupled to the conductive frame. The inner walls of the conductive frame, the top surface of the printed circuit board and the lid define a shield surrounding the circuit region.

In another representative embodiment, a conductive frame for shielding a high-frequency circuit, at least a portion of which being located on a printed circuit board, includes a bottom surface, inner side walls and a connector hole. The bottom surface contacts a top surface of the printed circuit board. The inner side walls define an opening corresponding to the portion of the high-frequency circuit located on the printed circuit board, the high-frequency circuit region being shielded by the inner side walls of the opening, the top surface of the printed circuit board and a lid affixed to a top surface of the conductive frame. The connector hole provides an interface between the shielded high-frequency circuit region and a signal connector, which includes a pin insertable through the hole and contacting a transmission line on the printed circuit board in the high-frequency circuit region, coupling at least millimeter-wave signals to the high-frequency circuit. Moreover, the conductive frame is adapted to receive an outer conductor of a connector

In another representative embodiment, a shield for a high-frequency circuit includes a conductive frame contacting a top conductive layer of a printed circuit board, a backing plate contacting a bottom surface of the printed circuit board, and a coaxial connector. The conductive frame defines an opening corresponding to a high-frequency circuit region located on the printed circuit board. The high-frequency circuit region is shielded by walls of the opening, the top conductive layer of the printed circuit board and a lid electrically coupled to the conductive frame. The backing plate attaches to the conductive frame and causes the conductive frame to exert pressure on the printed circuit board to enhance a contact between the top conductive layer of the printed circuit board and the conductive frame. A portion of the coaxial connector passes through a hole in the conductive frame, for interfacing the shielded high-frequency circuit region with a coaxial cable. At least an outer conductor of the coaxial connector is electrically coupled to the conductive frame, wherein the outer conductor is disposed within the conductive frame. Also, at least one of electrical power, control signals and low frequency microwave signals accesses the shielded high-frequency region through traces on an inner layer of the printed circuit board.

### BRIEF DESCRIPTION OF THE DRAWINGS

The present teachings are best understood from the following detailed description when read with the accompanying drawing figures. The features are not necessarily drawn to scale. Wherever practical, like reference numerals refer to like features.

FIG. 1 is a top perspective view of a shielded millimeter-wave circuit module, in accordance with a representative embodiment.

FIG. 2 is a cut-away view of the shielded millimeter-wave circuit depicted in FIG. 1, in accordance with a representative embodiment.

FIG. 3 is a top perspective view of a shielded millimeter-wave circuit module, in accordance with a representative embodiment.

FIG. 4 is a bottom perspective view of the shielded millimeter-wave circuit module depicted in FIG. 3, in accordance with a representative embodiment.

FIG. 5 is a bottom perspective view of a metal frame of the shielded millimeter-wave circuit module depicted in FIG. 3, in accordance with a representative embodiment.

FIG. 6 is a cut-away view of the metal frame depicted in FIG. 5, in accordance with a representative embodiment.

FIG. 7 is a top perspective view of a shielded millimeter-wave circuit module, in accordance with a representative embodiment.

### DETAILED DESCRIPTION

In the following detailed description, for purposes of explanation and not limitation, representative embodiments disclosing specific details are set forth in order to provide a thorough understanding of the present teachings. Descriptions of well-known devices, hardware, software, firmware, methods and systems may be omitted so as to avoid obscuring the description of the example embodiments. Nonetheless, such hardware, software, firmware, devices, methods and systems that are within the purview of one of ordinary skill in the art may be used in accordance with the representative embodiments.

As used herein, the term ‘high-frequency’ means frequencies in the microwave frequency band and the millimeter-wave frequency band. The shielded high-frequency circuit modules of the present teachings are contemplated for use with microwave frequency and millimeter-wave frequency circuits, components and systems. Microwaves are electromagnetic waves having frequencies within the range of 300 MHz to 300 GHz. Millimeter-waves are a subset of microwaves, having frequencies within the range of 30 GHz to 300 GHz. Notably, embodiments are often described in connection with millimeter-wave applications. It is emphasized that this is merely illustrative and that the present teachings are contemplated for use in other high-frequency components, circuits and systems. Furthermore, the present teachings are contemplated for use in other frequency bands/subbands (e.g., RF) as well.

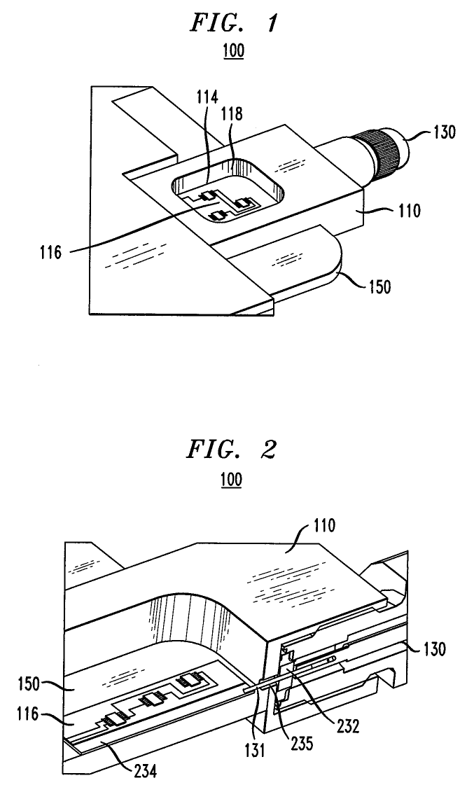

FIG. 1 is a perspective view of a shielded millimeter-wave circuit module 100, according to an representative embodiment of the disclosure. The shielded millimeter-wave circuit module 100 includes an electrically conductive frame (referred to as a conductive frame), such as a metal frame 110, mechanically and electrically connected to a printed circuit board (PCB) 150; although the frame 10 may comprise other electrically conductive materials without departing from the spirit and scope of the present teachings. Such materials include, but are not limited to metal alloys, multilayer metals/metal alloys, conductive composite materials known to one of ordinary skill in the art. The metal frame 10 includes an opening that defines a circuit region 114 on the surface of the PCB 150, which is the shielded area. The circuit region 114 may include wirebonded components, such as thin film circuits 116 and integrated circuits (ICs) (shown conceptually), commonly used in millimeter wave circuits. The thin film circuits 116 are typically passive circuits, and may include transmission lines, resistors, capacitors and inductors, formed by patterned materials on electrically insulating substrates, such as alumina, sapphire, silica, aluminum nitride, beryllia and other materials known to one of ordinary skill in the art.

The metal frame 110 also includes inner perimeter walls 118, which serve as walls of the shield between the circuit region 114 and other components of the PCB 150 outside of the metal frame 110, as well as components external to the PCB 150. The top portion of the shield is provided by a lid (not shown), which covers the circuit region 114. The lid may be made of metal or other conductive material. Also, the lid may be a separate component or it may be formed, for example, by a PCB in another circuit adjacent to the PCB 150 and/or the metal frame 110. The bottom portion or base of the shield is provided by the top surface of the PCB 150, which is a metal layer, as discussed below.

The connections or joints between the metal lid and the metal frame 110, and between the metal frame 110 and a top (e.g., metal) surface of the PCB 150 are conductive, to form a substantially continuous electromagnetic shield, e.g., around the circuit region 114. This continuously shielded enclosure may also form an environmental enclosure, protecting internal components from mechanical damage and ambient substances (e.g., moisture) that may contribute to corrosion.

The PCB 150 is illustratively a multilayered printed circuit board, which includes layers of metal separated by layers of dielectric material, interconnected by vias. In a representative embodiment, the PCB 150 includes six metal layers, for example, laminated with epoxy-glass-silica-fill laminate dielectric layers. Blind and through vias are used for transitions and shielding. Wirebond regions may be selectively plated with bondable gold, for example.

In addition to serving as the shield base, the PCB 150 is adapted to support the interconnection of low-frequency, microwave and mm-wave electronic components of the millimeter-wave circuit. Components normally used on PCBs can be suitably attached and included in the millimeter-wave circuit module 100. The mm-wave components are illustratively attached and electrically connected to the PCB 150 by standard surface-mount technology (SMT), by known die attach and wirebond techniques, or by other methods within the purview of one of ordinary skill in the art. The use of the PCB 150 as the base of the shielded area fosters the combination the low-frequency, microwave and millimeter-wave portions of the millimeter wave circuit with the millimeter-wave portions into a single physical circuit. Accordingly, the physical circuit is lower in cost, lower in weight and higher in density.

A coaxial connector 130 is attached to the metal frame 110 to provide signals to the circuit region 114, including the high-frequency, millimeter-wave signals. As shown in FIG. 2, which depicts a cut-away view of the shielded millimeter-wave circuit module 100 according to a representative embodiment, the coaxial connector 130 is insertable within a hole through the metal frame 110. In an embodiment, an outer conductor of the coaxial connector 130 is electrically coupled to the metal frame 110, and maintains substantially constant impedance. Also, the coaxial connector 130 is mechanically supported by the metal body of the metal frame 110. Furthermore, in addition to being electrically coupled to the metal frame 110, the outer conductor of the coaxial connector is disposed within the metal frame 110 and is mechanically connected to the metal frame 110. Illustratively, the mechanical connection may be effected by one of a variety of known methods, such as by solder or mechanical fastener (e.g., a screw).

The coaxial connector 130 interfaces with a coaxial cable (not pictured) outside the shielded millimeter-wave circuit module 100 and with a microstrip transmission line 234 (FIG. 2) on a thin film circuit 116 inside the shielded millimeter-wave circuit module 100 (e.g., in the circuit region 114). For example, a center pin 131 of the coaxial connector 130 may pass through a connector hole 235 (also referred as a connector channel) to as a defined by the metal frame 110, and contact the microstrip transmission line 234. Notably, the connector hole 235 forms a substantially electrically and physically enclosing path through the metal frame 110. In an embodiment, the center pin 131 may be mechanically connected to the microstrip transmission line 234, for example, by solder or a mesh bond connection. Also, the transmission line 234 may alternatively be a coplanar waveguide, a coplanar strip, a balanced strip, a suspended stripline, or the like. The coaxial connector 130 may have a coaxial glass-to-metal seal 232 to provide an environmental barrier between the cable-side (outside) and the circuit-side (inside) of the shielded millimeter-wave circuit module 100.

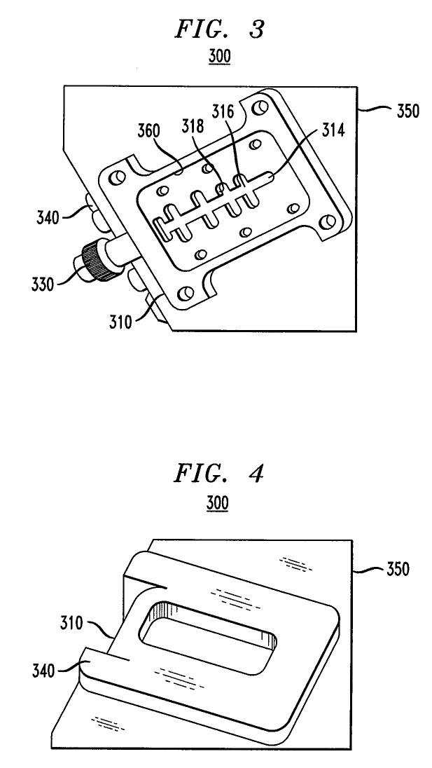

FIG. 3 is a top perspective view of a shielded millimeter-wave circuit module 300, according to a representative embodiment, which includes a backing plate 340, in addition to many of the features described previously in connection with FIGS. 1 and 2. The details of the features described with respect to FIGS. 1 and 2 will not be repeated to avoid obscuring the presently described embodiment.

The shielded millimeter-wave circuit module 300 generally includes a conductive frame, such as a metal frame 310, contacting at top conductive, e.g., metal, surface of a PCB 350. The metal frame 310 defines a circuit region 314 on the surface of the PCB 350, which is to be shielded. The backing plate 340 mechanically attaches to the metal frame 310, causing the metal frame 310 to exert pressure onto the top surface of the PCB 350. Also, the coaxial connector 330 is connected to the metal frame 310 to enable millimeter wave signals to couple to the shielded circuit region 314, as discussed above with respect to the coaxial connector 130.

The shielded circuit region 314 includes wirebonded components, such as thin film circuits 316 and ICs. As in FIG. 1, the inner perimeter walls 318 of the metal frame 310 serve as walls to shield the circuit region 314. The remainder of the shield is provided by a metal lid (not pictured) and the top surface of the PCB 350, which serves as the shield base.

However, the inner perimeter walls 318 of the metal frame 310 in FIG. 3 define a circuit area specifically designed for millimeter-waves. The illustrative pattern of the shielded circuit region 314 is designed to prevent negative transmission effects, such as resonances. For example, when a source of electromagnetic energy is enclosed in a conductor, radiated energy can reflect from the conductor surfaces. When the frequency of the electromagnetic wave is near a fundamental/natural frequency of a shielded circuit, then resonances may occur. As is known, resonances can be detrimental to the performance of the microwave circuit, especially cavity resonances. Most notably, resonances serve to reduce the efficiency of the circuit. On a Smith Chart, these resonances often manifest as ‘suck-outs’ or energy drains, and thus cause the circuit to suffer excess loss in portions of the operating frequencies of the circuit where the suckouts occur.

Therefore, the dimensions of the metal frame 310 and the pattern of the shielded circuit region 314 are selected such that, when enclosed, the fundamental frequency supported by the shielded circuit region 314 occurs at frequencies higher than the operating range of the circuit. Stated differently, the dimensions of the metal frame 310 and pattern of the shielded circuit region 314 are selected so that fundamental frequencies in the operating range of the circuit are not supported. In certain embodiments, the widths and heights of the various channels (e.g., the inner perimeter walls 318) may be specified to be less than one-half wavelength of the highest operating frequency, after accounting for all materials present. It is understood that the particular size and shape of the pattern of the shielded circuit region 314 may vary without affecting the scope and spirit of the present teachings and that other sizes and pattern shapes are contemplated.

In addition, to minimize resonances further, or when undesirable out-of-band resonances otherwise occur, electromagnetic absorbing materials may be employed.

FIG. 4 is a bottom perspective view of the shielded millimeter-wave circuit module 300, in accordance with a representative embodiment. The backing plate 340 provides a rigid support to which the metal frame 310 is attached for securely connecting the metal frame 310 to the PCB 350. The backing plate 340 may be mechanically attached to the metal frame 310, for example, using screws or clamps (not shown), with the PCB 350 positioned between the backing plate 340 and the metal frame 310. This causes a bottom surface of the perimeter of the metal frame 310 to exert a substantially constant pressure against the top surface of the PCB 350. In an embodiment, this metal-to-metal contact between the metal frame 310 and the top metal layer of the PCB 350 may be sufficient to provide the necessary conductive coupling and environmental seal for shielding purposes. Also, in an embodiment, the backing plate 340 and/or the metal frame 310 may be detachable.

The PCB 350 is designed and fabricated with supporting features for the millimeter-wave circuit module 300. For example, while PCB technology is not normally well-suited to the construction of millimeter-wave circuit paths, for example, due to the necessary high connection tolerances, PCB technology is able to accommodate comparably low-frequency associated support functionality, such as power supplies and control circuits. By supplying power through the PCB 350, there is no need for the use of separate DC feeds for the millimeter-wave circuit. Also, the low-frequency support circuitry, which is generally more complex and includes more components than the high-frequency millimeter-wave circuit path, can be more efficiently fabricated on the PCB 350.

The regions of the PCB 350 where the metal frame 310 connects may be clad with metal or other conductive material, preferably gold or other noble metal, to better enable an electrically conductive contact between the PCB 350 and the metal frame 310. Also, the top surface of the PCB 350 may be clad with similar or the same material also on the interior of the metal frame 310 to act as a ground plane and shield. The top conductive layer of the PCB 350 has openings as necessary to allow transmission lines using the top conductive layer and via connections to the inner conductive layers. Transmission lines and vias in the PCB 350 may carry microwave signals within the shielded millimeter-wave circuit module 300 and to connect such signals with circuits outside that region.

The millimeter-wave circuit path may include ICs, thin-film circuits, wirebonds, and other components that are mounted on the PCB 350 and within channels and cavities that are machined or otherwise formed in the metal frame 310. The millimeter-wave circuit path residing within the shielded region may connect directly to low-frequency or microwave circuits in the PCB 350, usually through wirebonds to pads on the PCB 350.

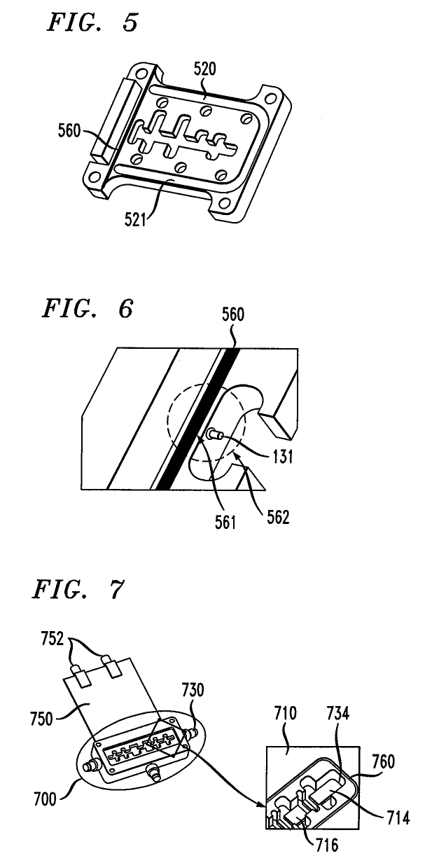

FIG. 5 is a bottom perspective view of the metal frame 310 of the shielded millimeter-wave circuit module 300 depicted in FIG. 3. The bottom surface of the illustrative metal frame 310 includes a gasket groove 520, which is defined along a portion of the perimeter of the metal frame 310. The gasket groove 520 includes a gasket 521 (not shown), which enhances the seal between the metal frame 310 and the PCB 350. Alternatively, solder (e.g., lead free solder) or a conductive adhesive (e.g., silver filled epoxy) may be applied in the joint between the metal frame 310 and the top layer of the PCB 350, to assure a continuous conductive contact. In addition, a gasket, solder and/or conductive epoxy may be applied to joints between the metal frame 310 and the metal lid. These features may be used alone or in any combination to achieve the desired conductive connection and environmental seal, without departing from the spirit and scope of the present teachings.

FIG. 5 also shows a connector launch groove 560, an expanded view of which is depicted in FIG. 6. The connector launch groove 560 concentrates mechanical forces to a connector launch region 562 at a groove edge 561, promoting low resistance ground contact. Other surface treatments, such as diamond-particle interconnect, may be used to facilitate the conductive connection.

With respect to fabrication and assembly, in a representative embodiment, the shielded millimeter-wave circuit module 300 is assembled on the PCB 350 after SMT assembly is completed. In other words, all circuit components, including ICs, thin film circuits 316 and other wirebonded components, are attached to the PCB 350 before the metal frame 310 is assembled. The first assembly process may be a two-sided surface mount attach, in which the SMT components are attached to both sides of the PCB 350 (top and bottom). The SMT components may include connectors, resistors, capacitors, inductors, transistors, diodes, packaged ICs, standard shields, and any component that can be attached during an SMT process. SMT shielded microwave connectors and custom walls that are part of microwave circuits may also be attached to the top surface of the PCB 350 during this process. The circuit design and layout dictate the fabrication and assembly tolerances. These tolerances are a primary limitation on the frequency range of circuit performance.

The thin film circuits 316, ICs and other wirebonded components may then be attached to the PCB 350. This is typically done in two phases (layers), i.e., in order to accommodate ICs mounted on shims or the thin film circuits 316. The wirebond connections may be made with wedge bonds, for example. Components of the shielded millimeter-wave circuit module 310 to be wirebonded are mounted to the PCB 350, e.g., on the top metal ground plane, and connected to each other or to the PCB 350 with edge-to-edge wirebonds, for example. Placement accuracy of the millimeter-wave components is specified to limit reflections and parasitics. All components within and outside the shielded region (e.g., the circuit region 314) may attached to the respective regions of the PCB 150 and wirebonded in the same process.

In a representative embodiment, the metal frame 310 is formed by a machining method, such as mechanical milling, able to accommodate specified feature sizes and tolerances. The metal frame 310 is formed to include various features for enabling assembly of the shielded millimeter-wave circuit module 300. For example, the metal frame 310 may include features for mounting connectors (e.g., coaxial connector 330) and launching a low-reflection electromagnetic mode to a microstrip circuit. It may also include channels or cavities, bounded by the PCB 350, the metal frame 310 and the lid, in which microwave circuit components may be mounted onto the top surface of the PCB 150. The metal frame 310 may also include features for mounting the metal lid, for clamping the metal frame 310 onto the PCB 350 with the backing plate 340, and for enhancing the electrical and mechanical contact between the metal frame 310 and the PCB 350.

The signal connector (e.g., the coaxial connector 330) is inserted into the metal frame 310 before it is attached to the PCB 350. Alignment of the connector 330 to the circuit is critical to the circuit performance, which is accounted for by tolerances of the millimeter-wave circuit module 300. Precision-placed alignment components may be included as guides to prevent damage to wirebonded components and to ensure proper positioning of the metal frame 310. The alignment components can be included among the circuit components, such as the thin film connector launch circuits, or they can be dedicated parts. A center pin 131 (FIGS. 2 and 6) of the connector 330 may be connected to the thin film connector launch circuits by known methods, such as soldering or wirebonding.

The backing plate 340 is attached to securely clamp the metal frame 310 to the PCB 350, as discussed above. The connector launch groove 560 in the connector launch region 562 of the connector 330, as shown in FIGS. 5 and 6, promotes low resistance ground contact for the connector launch (e.g., the transition from a coaxial transmission line to a microstripline). Other surface treatments, such as diamond-particle interconnect, may be used to further facilitate the conductive connection, assuring the electrical coupling between the metal frame 310 and the PCB 350.

In various embodiments, additional features may be included to enhance the conductive connection. For example, as shown in FIG. 5, the gasket 521 may be inserted in the gasket groove 520 to seal any gap that may form between the metal frame 310 and the PCB 350. Alternatively or in addition, a conductive epoxy (not pictured) may be applied in the joint between the metal frame 310 and the top layer of the PCB 350.

After the electrical components have been assembled and the metal frame 310 attached, an electrical test may be performed to confirm basic functionality before the lid is attached. Depending on the results of the testing, rework may be performed as necessary prior to assembly of the lid.

The lid may be fabricated in a conductive material, such as metal, by an appropriate process, such as machining, stamping, or the like. The lid may be clamped to the metal frame 310 by mechanical fasteners (not pictured), for example, that screw into the backing plate 340. In an embodiment, the lid may fit within a recess 360 defined in the top surface of the metal frame 310, shown in FIG. 3. A joint between the lid and metal frame 310 should be continuous and conductive. A shielding gasket or conductive adhesive (e.g., epoxy) may be used to seal the joint between the metal frame 310 and the lid. Lids for shielded microwave or millimeter-wave circuits positioned elsewhere on the PCB 350 may be attached at this stage, as well.

Heat sinks, brackets and external components may be attached in the last assembly step. For example, circuit components produce heat that must be dissipated to stay within respective operating temperature ranges. Temperature may be managed in the millimeter-wave circuit module 300 by providing thermally conducting features that direct heat to surfaces, where it may be dissipated to the environment (ambient). Therefore, a heat sink (not pictured) may be attached or otherwise thermally coupled to the lid and/or the backing plate 340. Also, heat-generating components may be mounted on thermally conducting elements (e.g., layers), either separate elements or elements integral to the PCB 350, which efficiently spread the thermal energy. By spreading the thermal energy, the thermal resistance in passing through subsequent materials is reduced.

Further, through vias and metal planes provide thermal conducting structures in the PCB 350. For example, there are two heat paths from components within the shielded circuit region 314 to ambient atmosphere. First, heat may be dissipated down through the device to heat spreading layer(s), laterally across the heat-spreading layer(s), laterally through the PCB 350, up through the metal frame 310, and out the metal lid. Second, heat may be dissipated down through the device to heat spreading layer(s), laterally across the heat-spreading layer(s), down through the PCB 350, and out the bottom of the PCB 350.

The shielded millimeter-wave circuit module 300 may then be tested again as a final check. The circuit within the shielded millimeter-wave circuit module 300 may be reworked, if necessary, by removing the lid, which may be detachable.

FIG. 7 is a top perspective view of a printed circuit board PCB 750 having an attached shielded millimeter-wave circuit module 700, according to a representative embodiment, which does not include a backing plate. The module 700 includes many features described previously in connection with FIGS. 1-6. The details of these features are not repeated to avoid obscuring the presently described embodiment. The millimeter-wave circuit module 700 includes a conductive frame, such as a metal frame 710, which defines an open shielded circuit region 714, designed to minimize negative effects of transmission, such as cavity resonances. The shielded circuit region 714 includes thin-film circuits 716 and ICs mounted to the PCB 750. A lid (not pictured) is inserted over the shielded circuit region 714 within the recess 760. Thus, the circuit region 714 is shielded, electromagnetically and environmentally, by the top surface of the PCB 750, the inner sidewalls 734 of the metal frame 710 and the lid. Joints between each of these components may be further sealed, using gaskets and/or adhesive formed of conductive materials, to assure secure mechanical contact and electrical coupling.

The illustrative millimeter-wave circuit module 700 of FIG. 7 includes three coaxial connectors 730 for signals, including the millimeter wave signals. The PCB 750 may include separate connectors 752, as needed, to accommodate other signals, including microwave signals, lower frequency signals, electrical power and control signals. In an embodiment, power, control signals and microwave circuitry are predominantly located outside of the shielded millimeter-wave circuit module regions, as discussed above. Electrical power, control voltages and microwave signals may be connected to the shielded millimeter-wave circuit 700 through traces on inner layers of the PCB 750. The microwave signals, in particular, may be connected to the shielded millimeter-wave circuit by stripline transmission lines in the PCB 750 that connect to blind vias within the shielded millimeter-wave circuit module 700. A minimum of millimeter-wave circuitry may be contained within the shielded millimeter-wave circuit module 700.

Millimeter-wave signals are substantially contained within the shielded millimeter-wave circuit module regions. The millimeter-wave input and output signals are connected to the shielded millimeter-wave circuit module 700 through constant-impedance shielded coaxial microwave connectors 730 that are mounted in the metal frame 710. The millimeter-wave signals may, for example, be routed within the shielded millimeter-wave circuit module 700 using microstrip transmission line 716, e.g., on thin film circuits.

Connection among various circuit components may be made using known PCB technology without affecting the shielding attributes of the disclosed embodiments. For example, bare die may be connected to each other and the PCB 750 using wirebonds. Components requiring a backside connection to ground, or some circuit potential, may be connected through a die attach joint. Connections to packaged components, e.g., attached by SMT, may be made through solder joints. Arrays of through vias may be used for shielding within the PCB 750 and may be located within or outside of the shielded millimeter-wave circuit module 700. The via arrays may be interrupted to allow passage of traces within the PCB 750. Wirebonds may connect pads on the PCB 750 to the millimeter-wave circuit inside the shield area.

The various circuit components perform actions on the signals, such as controlling voltages or currents, switching, attenuating, amplifying, mixing, sampling, filtering or other functions that may be required in high-frequency analog or digital circuits. Circuit components may include all parts of the circuit, including those attached to the PCB 750 and the PCB 750, itself. For example, patterns of metal layers of the PCB 750 may form filtering elements.

Although not shown, integration may be further enhanced by multiple shielded millimeter-wave circuit modules 700 being arranged on a single PCB 750. This enables a single PCB 750 to support multiple shielded regions, each having separate shielded signal connectors.

As described previously, the millimeter-wave circuit module 700 provides shielding from electromagnetic energy in the shielded regions of the circuit. Further, the millimeter-wave circuit module 700 shields provide environmental and mechanical protection normally required for bare die. The construction of the millimeter-wave circuit module 700 shield reduces the ingress of moisture, which would otherwise significantly degrade reliability. For example, moisture essentially does not pass through metals, but it will pass through most PCB dielectric materials and epoxies, e.g., used for lid attachment. Moisture ingress is minimized by cladding surfaces of the PCB 750 with metal, where possible, and by attaching the metal frame 710 and lid with thin, wide joints.

Although the present teachings have been described in detail with reference to particular embodiments, persons possessing ordinary skill in the art to which the present teachings pertain will appreciate that various modifications and enhancements may be made without departing from the spirit and scope of the claims that follow. Also, the various devices and methods described herein are included by way of example only and not in any limiting sense.

What is claimed:

1. A shielded high-frequency circuit module, comprising:
a conductive frame electrically coupled to a top surface of a printed circuit board and a lid, the conductive frame comprising inner walls defining a circuit region, at least a portion of the circuit region comprising a circuit on the top surface of the printed circuit board; and
a connector adapted to interface the circuit region with high-frequency signals outside the conductive frame, the connector comprising an outer conductor disposed within the conductive frame with at least a portion of the connector being electrically coupled to the conductive frame, wherein the inner walls of the conductive frame, the top surface of the printed circuit board and the lid define a shield surrounding the circuit region.

2. The shielded high-frequency circuit module of claim 1, wherein the conductive frame comprises a metal frame and the top surface of the printed circuit board comprises a metal layer.

3. The shielded high-frequency circuit module of claim 2, wherein the lid comprises a surface of another printed circuit board.

4. The shielded high-frequency circuit module of claim 2, wherein the circuit on the top surface of the printed circuit board comprises wirebonded die.

5. The shielded high-frequency circuit module of claim 1, wherein the conductive frame comprises a connector launch groove adapted to increase contact pressure on a groove edge of a connector launch, promoting a low resistance ground contact.

6. The shielded high-frequency circuit module of claim 1, wherein the conductive frame is mechanically connected to the top surface of the printed circuit board through an electrically conductive material.

7. The shielded high-frequency circuit module of claim 6, wherein the electrically conductive material comprises one of a gasket or an adhesive.

8. The shielded high-frequency circuit module of claim 6, wherein the electrically conductive material comprises one of a solder or a braze.

9. The shielded high-frequency circuit module of claim 1, further comprising:
a backing plate abutting a bottom surface of the printed circuit board and connected to the conductive frame, the backing plate adapted to increase a pressure between the conductive frame and the top surface of the printed circuit board to enhance the electronic coupling.

10. The shielded high-frequency circuit module of claim 9, further comprising:
a heat sink thermally coupled to at least one of the lid and the backing plate.

11. A conductive frame for shielding a high-frequency circuit, at least a portion of the high-frequency circuit being located on a printed circuit board, the conductive frame comprising:
a bottom surface for contacting a top surface of the printed circuit board;
a plurality of inner side walls for defining an opening corresponding to the portion of the high-frequency circuit located on the printed circuit board, the high-frequency circuit region being shielded by the plurality of inner side walls of the opening, the top surface of the printed circuit board and a lid affixed to a top surface of the conductive frame; and
a connector hole operative to provide an interface between the shielded high-frequency circuit region and a signal connector, the signal connector comprising a pin insertable through the hole and contacting a transmission line on the printed circuit board in the high-frequency circuit region coupling at least millimeter-wave signals to the high-frequency circuit, wherein the conductive frame is adapted to receive an outer conductor of a connector.

12. The conductive frame of claim 11, wherein the bottom surface of the conductive frame is electrically coupled to the top surface of the printed circuit board and the top surface of the conductive frame is electrically coupled to the lid.

13. The conductive frame of claim 12, wherein the bottom surface of the conductive frame defines a gasket groove for containing a shielding gasket, the shielding gasket enhancing a conductive contact between the bottom surface of the conductive frame and the top surface of the printed circuit board.

14. The conductive frame of claim 12, wherein a conductive epoxy substantially seals a joint between the bottom surface of the conductive frame and the top surface of the printed circuit board, the conductive epoxy enhancing a conductive contact between the bottom surface of the conductive frame and the top surface of the printed circuit board.

15. The conductive frame of claim 11, wherein the signal connector comprises a constant-impedance coaxial cable connector for interfacing with a coaxial cable.

16. The conductive frame of claim 11, wherein the transmission line comprises one of a microstrip or a planar transmission line.

17. The conductive frame of claim 11, further comprising:
at least one connector for attaching to a backing plate contacting a bottom surface of the printed circuit board, the backing plate causing the bottom surface of the conductive frame to exert pressure on the printed circuit board to enhance contact with the top surface of the printed circuit board.

18. The conductive frame of claim 11, wherein at least one of electrical power, control voltages and microwave signals connect to the shielded portion of the high-frequency circuit through traces on inner layers of the printed circuit board.

19. The conductive frame of claim 11, further comprising:
a connector launch groove for selectively enhancing conductive contact between a portion of the bottom surface of the conductive frame and the top surface of the printed circuit board.

20. A shield for a high-frequency circuit, comprising:
a conductive frame contacting a top conductive layer of a printed circuit board, the conductive frame defining an opening corresponding to a high-frequency circuit region located on the printed circuit board, the high-frequency circuit region being shielded by walls of the opening, the top conductive layer of the printed circuit board and a lid electrically coupled to the conductive frame;
a backing plate contacting a bottom surface of the printed circuit board and attaching to the conductive frame, the backing plate causing the conductive frame to exert pressure on the printed circuit board to enhance a contact between the top conductive layer of the printed circuit board and the conductive frame; and
a coaxial connector, a portion of which passes through a connector hole in the conductive frame, for interfacing the shielded high-frequency circuit region with a coaxial cable, at least an outer conductor of the coaxial connector being electrically coupled to the conductive frame and being disposed within the conductive frame, wherein at least one of electrical power, control signals and low frequency microwave signals accesses the shielded high-frequency region through traces on an inner layer of the printed circuit board.
